(19) United States
(12) Patent Application Publication
(10) Pub. No.: US 2007/0132051 A1
(43) Pub. Date: Jun. 14, 2007

(54) Solid-state imaging device and manufacturing method for the same

(75) Inventor: Takeo Yoshida, Kurokawa-gun (JP)

Correspondence Address: BIRCH STEWART KOLASCH & BIRCH, PO BOX 747, FALLS CHURCH, VA, 22040-0747, US

(73) Assignee: FUJIFILM Corporation

(21) Appl. No.: 11/604,742

(22) Filed: Nov. 28, 2006

(30) Foreign Application Priority Data
Nov. 30, 2005 (JP) P2005-346449

(51) Int. Cl. H01L 31/0232

(52) U.S. Cl. 257/432

(57) ABSTRACT

A solid-state imaging device is provided and has: a plurality of photoelectric conversion elements; and a plurality of gapless microlenses formed above the plurality of photoelectric conversion elements. The focal length of each of the plurality of microlenses is determined according to a color detected by a photoelectric conversion element provided under the each of the plurality of microlenses.

### BACKGROUND OF THE INVENTION

1. Field of the Invention

The present invention relates to a manufacturing method for a solid-image device having a gapless microlens.

2. Description of Related Art

A related solid-image imaging device is provided with a microlens array to collect light to a photoelectric conversion element. A gapless microlens array configured to have no gap between adjacent microlenses is known as the microlens array (see JP-A-10-206605, JP-A-5-145813 and JP-A-2000-304906).

A manufacturing method for a gapless microlens array is as follows. First, a plurality of rectangular resists are formed above a photoelectric conversion element so that the intervals between the adjacent ones of the resists are uniform. Subsequently, the resists are reflowed. Then, the reflowed resists are hardened by implanting ions into the reflowed resists. Thus, a plurality of upwardly convex lenses are formed. Subsequently, an overcoat film is formed on the plurality of the lenses by spin-coating. Then, the gap among the plurality of the lenses is closed by the overcoat film. Consequently, a gapless microlens array is formed. According to this method, after the overcoat film is formed, the curvature of each of the microlenses is uniform over the entire microlens array.

Generally, a solid-state imaging device has color filters, which respectively correspond to three colors or more, and an optical layer that includes microlenses and is provided above the color filters. The wavelength of light transmitted by each of the color filters is not constant. The absorption efficiency at each wavelength of light of each photodiode serving as a photoelectric conversion element depends on the depths of the photodiodes. In a related solid-state imaging device, the curvature of each of the microlenses formed above the photodiode is constant. Also, the focal length of each of the microlenses is constant. That is, regardless of the fact that light beams of different wavelengths are incident on photodiodes, respectively, light beams are collected at each of the photodiodes at the same depth. Thus, the optical intensity of each color is not optimal.

### SUMMARY OF THE INVENTION

An object of an illustrative, non-limiting embodiment of the invention is to provide a solid-state imaging device enabled to optimize the optical intensity of each color. Also, another object of an illustrative, non-limiting embodiment of the invention is to provide a manufacturing method suitable for manufacturing such a solid-state imaging device.

According to an aspect of the invention, there is provided a solid-state imaging device including: a plurality of photoelectric conversion elements; and a plurality of microlenses above the plurality of photoelectric conversion elements. The plurality of microlenses being formed gaplessly. That is, two adjacent microlenses has no gap therebetween. This solid-state imaging device is configured so that the focal length of each of the plurality of microlenses is determined according to a color detected by a photoelectric conversion element provided under the each of the plurality of the microlenses.

A solid-state imaging device according to an aspect of the invention may be configured so that each of the plurality of microlenses includes a convex lens and an overcoat film which is formed on the convex lens and adjusts curvature of the convex lens.

According to another aspect of the invention, there is provided a manufacturing method for a solid-state imaging device including gapless microlenses, which includes a step of manufacturing the gapless microlenses. The step of manufacturing of the gapless microlenses includes: a lens forming step of forming a plurality of convex lenses above a plurality of photoelectric conversion elements; and an overcoat film forming step of forming an overcoat film, which adjusts curvature of each of the plurality of convex lenses, on the plurality of convex lenses. In the lens forming step, the plurality of convex lenses are formed so that when one of the plurality of convex lenses is selected as a lens, a distance between the lens and a convex lens adjacent to the lens changes according to a feature of a photoelectric conversion element under the lens.

A manufacturing method for a solid-state imaging device according to an aspect of the invention may be adapted so that the feature of the photoelectric conversion element is a color detected by the photoelectric conversion element.

The manufacturing method for a solid-state imaging device according to an aspect of the invention may be adapted so that the feature of the photoelectric conversion element is a sensitivity of the photoelectric conversion element.

The manufacturing method for a solid-state imaging device according to an aspect of the invention may be adapted so that the feature of the photoelectric conversion element is a position of the photoelectric conversion element.

### BRIEF DESCRIPTION OF THE DRAWINGS

The features of the invention will appear more fully upon consideration of the exemplary embodiments of the inventions, which are schematically set forth in the drawings, in which:

FIG. 1 is a schematic view illustrating a part of a solid-state imaging device that is an exemplary embodiment of the invention;

FIG. 2A is a schematic cross-sectional view taken on line a-a shown in FIG. 1, which illustrates R-color filters and parts provided thereon, FIG. 2B is a schematic cross-sectional view taken on line b-b shown in FIG. 1, which illustrates B-color filters and parts provided thereon;

FIGS. 3A to 3E are explanatory views illustrating a process of manufacturing the solid-state imaging device shown in FIG. 1;

FIGS. 4A to 4E are explanatory views illustrating a process of manufacturing the solid-state imaging device shown in FIG. 1; and

FIG. 5 is a plan view illustrating the solid-state imaging device obtained after performing resist-patterning.

### DETAILED DESCRIPTION OF THE EXEMPLARY EMBODIMENTS

Although the invention will be described below with reference to the exemplary embodiment thereof, the following exemplary embodiment and its modification do not restrict the invention.

According to an exemplary embodiment of the invention, a solid-state imaging device enabled to optimize the optical intensity of each color can be provided.

Hereinafter, exemplary embodiments according to the invention are described with reference to the accompanying drawings.

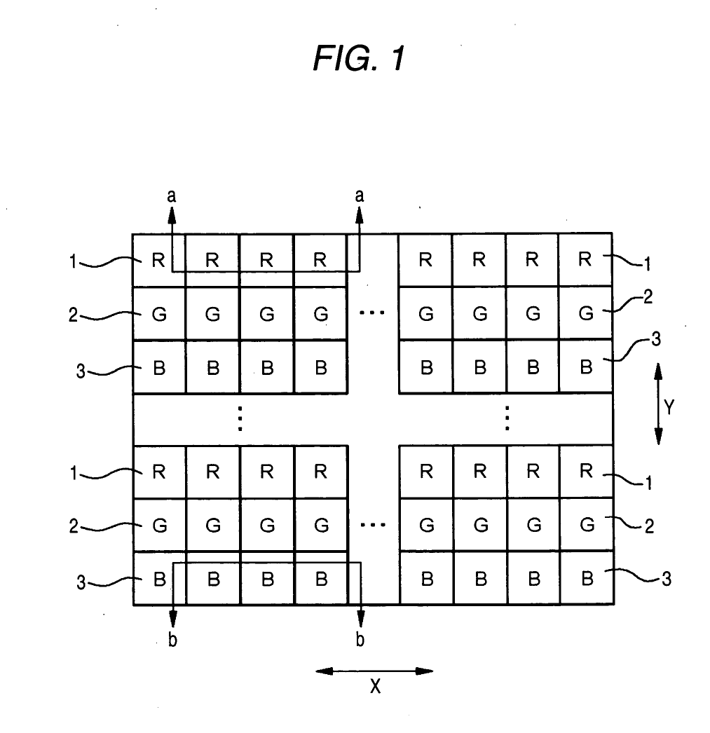

FIG. 1 is a schematic view illustrating a part of a solid-state imaging device that is an exemplary embodiment of the invention.

The solid-state imaging device shown in FIG. 1 has a plurality of pixel portions 1, 2, and 3 arranged in an X-direction and in a Y-direction perpendicular to the X-direction. Each of the pixel portions 1, 2, and 3 includes a photodiode serving as a photoelectric conversion element, a color filter formed above the photodiode, and a microlens formed above the color filter. The size in plan view of each of the pixel portions is equal to that of the color filter included therein.

The pixel portion 1 includes an R-color filter adapted to transmit red (R) light. Therefore, in FIG. 1, character “R” is added to the leading position of the name “pixel portion” thereof. The pixel portion 2 includes a G-color filter adapted to transmit green (G) light. Therefore, in FIG. 1, character “G” is added to the leading position of the name “pixel portion” thereof. The pixel portion 3 includes a B-color filter adapted to transmit blue (B) light. Therefore, in FIG. 1, character “B” is added to the leading position of the name “pixel portion” thereof. Hereunder, the pixel portions 1, 2, and 3 are referred to as an R-pixel portion, a G-pixel portion, and a B-pixel portion.

In the Y-direction, each of a set of R-pixel portions, a set of G-pixel portions, a set of B-pixel portions is arranged like a stripe. Incidentally, the arrangement of each kind of the pixels portions is not limited to that shown in FIG. 1. Various known arrangements can be employed as the arrangement of each kind of the pixels portions.

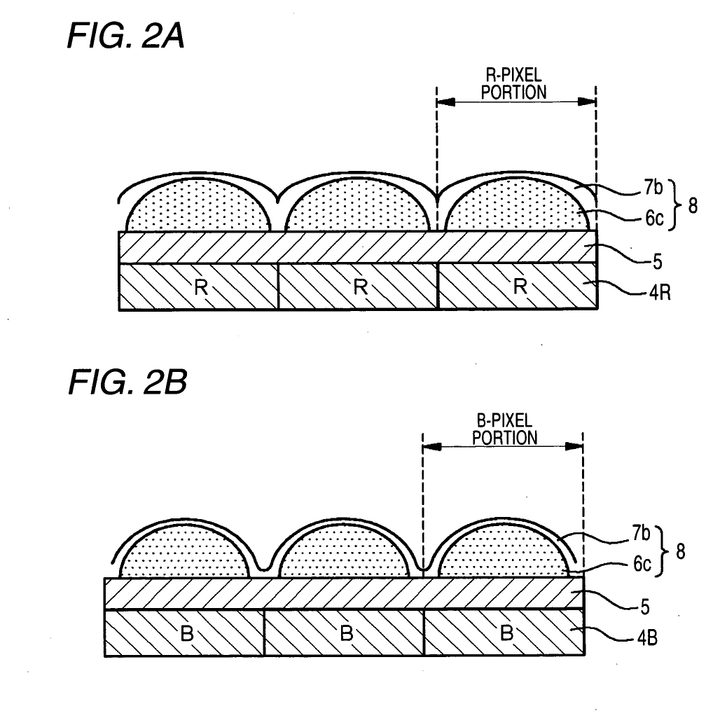

FIG. 2A is a schematic cross-sectional view taken on line a-a shown in FIG. 1, which illustrates R-color filters and parts provided thereon. FIG. 2B is a schematic cross-sectional view taken on line b-b shown in FIG. 1, which illustrates B-color filters and parts provided thereon.

As shown in FIGS. 2A and 2B, each of the B-pixel portions includes a B-color filter 4B. Each of the R-pixel portions includes an R-color filter 4R. A planarized film 5 is formed above each of the B-color filter 4B and the R-color filter 4R. An upwardly convex lens 6c made of a resin material is formed above each of the B-color filter 4B and an R-color filter 4R through the planarized film 5. The lens 6c is formed corresponding to each of the pixel portions. An overcoat film 7b operative to adjust the curvature of the lenses 6c is formed on the lenses 6c over the entire surface of the solid-state imaging device. The lens 6c and a part of the overcoat film 7b, which are included in each of the pixel portions, constitutes a microlens 8 adapted to collect light to the photodiode provided therein. The gap between the lenses 6c is filled with the overcoat film 7b. Thus, the microlens 8 included in each of the pixel portions is formed to be of the gapless type.

Although FIGS. 2A and 2B show only the B-pixel portions and the R-pixel portions, each of the G-pixel portions includes the G-color filter, a part of the planarized film 5, the lens 6c, and the part of the overcoat film 7b, similarly to the other kinds of pixel portions. The sizes of the lenses 6c included in the pixel portions differ from one another according to the kinds of the pixel portions, that is, the R-pixel portion, the G-pixel portion, and the B-pixel portion. The lens 6c included in the R-pixel portion is largest in size in plan view. The descending order of the size in plan view of those included in the other kinds of the pixel portions is that included in the G-pixel portion, and that included in the B-pixel portion. Hereunder, the microlenses 8 respectively included in the B-pixel portion, the R-pixel portion, and the G-pixel portion will be referred to as a B-microlens, an R-microlens, and a G-microlens, respectively.

The solid-state imaging device according to the invention features that the focal length of each of the plurality of the microlenses 8 is determined according to a color detected by the photodiode provided therebelow.

The B-microlens 8 is formed so that the focal length thereof reaches a value corresponding to a depth at which the B-light absorbing efficiency of the photodiode included in the B-pixel portion is highest. Similarly, the R-microlens 8 is formed so that the focal length thereof reaches a value corresponding to a depth at which the R-light absorbing efficiency of the photodiode included in the R-pixel portion is highest. Also, the G-microlens 8 is formed so that the focal length thereof reaches a value corresponding to a depth at which the G-light absorbing efficiency of the photodiode included in the G-pixel portion is highest.

With such a configuration, light of each wavelength transmitted by each of the color filters can efficiently be absorbed by the corresponding photodiode. The optical intensity of each color can be optimized.

The microlenses of the solid-state imaging device of the above configuration can basically be manufactured by a method which will be more specifically described later and is similar to a conventional method. That is, the microlenses of the solid-state imaging device of the above configuration can be manufactured by forming a plurality of lenses 6c on a planarized film 5 and by subsequently forming an overcoat film 7b on the plurality of lenses 6c through spin-coating.

In a case where one of the lens 6c is selected as a lens of interest, and where the gap between the lens 6c of interest and another of the other lenses 6c, which adjoins the lens 6c of interest, is wide, an overcoat material, which is applied onto the lenses 6c by spin-coating, flows into the gap and thinly spreads in parallel with the planarized film 5, so that the overcoat film's thickness in a direction perpendicular to the planarized film 5 is not large. Consequently, the microlens 8 including the lens 6c of interest and the overcoat film 7b maintains a curvature which is close to the curvature of the lens of interest 6c.

Conversely, in a case where the gap between the lens 6c of interest and another of the other lenses 6c, which adjoins the lens 6c of interest, is narrow, the overcoat material applied by spin-coating cannot spread very much in parallel with the planarized film 5 even when the overcoat material flows into the gap. Thus, the overcoat-film's thickness in the direction perpendicular to the planarized film 5 becomes thick. Consequently, the curvature of the microlens 8 including the lens 6c of interest and the overcoat film 7b is adjusted to be less than that of the lens 6c of interest.

In consideration of such facts, it is found that the curvature of the finally formed microlens 8 can be adjusted by preliminarily adjusting the gap between the lens 6c and the adjacent lens 6c. In a case where the curvature of the microlens 8 is small, the focal length thereof is long. In a case where the curvature of the microlens 8 is large, the focal length thereof is small. Therefore, according to the present embodiment, the focal length of each of the R-microlens 8, the G-microlens 8, and the B-microlens 8 is changed by utilizing these facts.

Hereinafter, the method of manufacturing the solid-state imaging device is more specifically described.

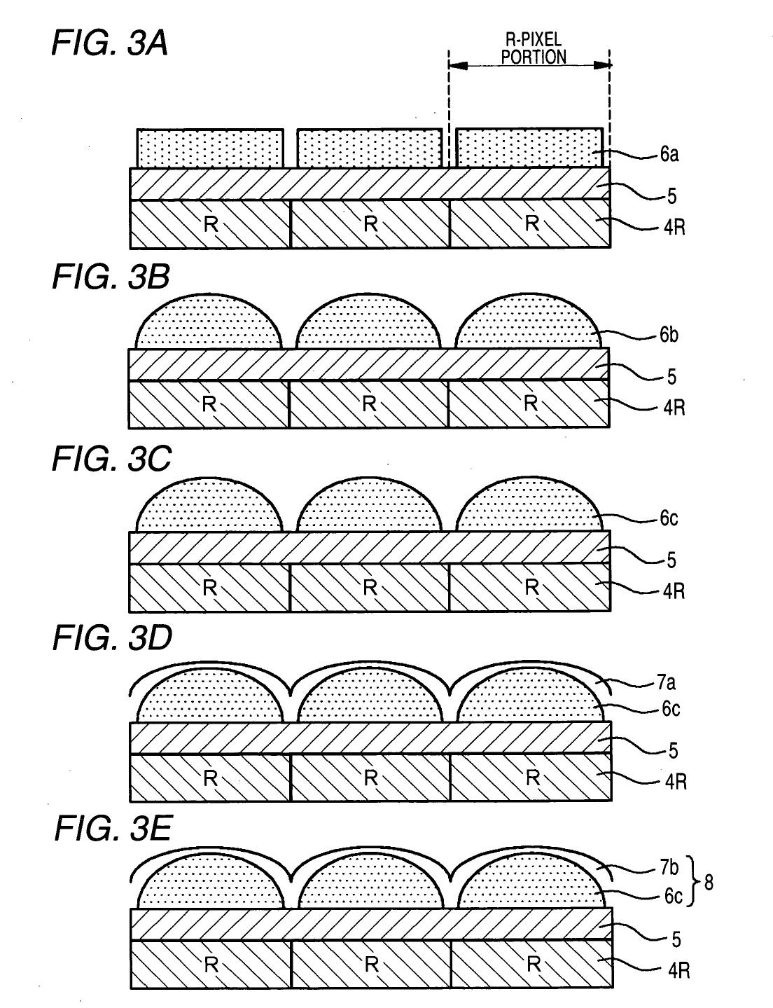

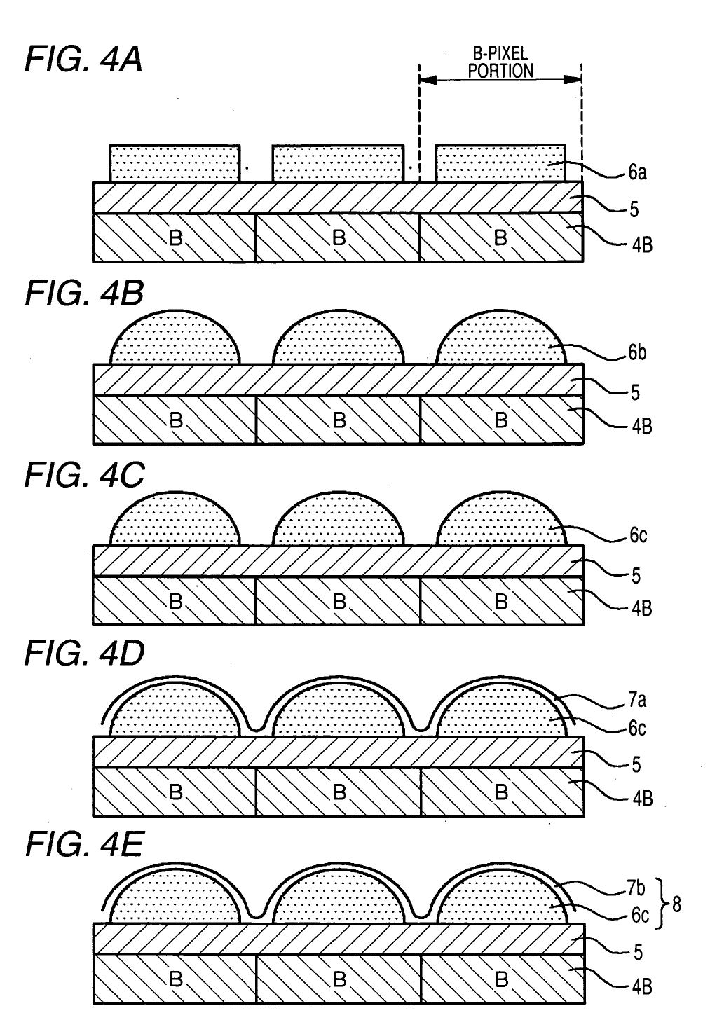

FIGS. 3A to 3E are cross-sectional views taken on line a-a shown in FIG. 2 and illustrate a process of manufacturing the solid-state imaging device shown in FIG. 1. FIGS. 4A to 4E are cross-sectional views taken on line b-b shown in FIG. 1 and illustrate a process of manufacturing the solid-state imaging device shown in FIG. 1. A process up to the formation of the planarized film 5 is similar to a conventional process. Thus, the description of the process up to the formation of the planarized film 5 is omitted herein.

As shown in FIGS. 3A and 4A, first, a resist for excimer laser exposure or ultraviolet exposure is applied onto the planarized film 5. Subsequently, the resist is patterned by performing exposure and development using ultraviolet light. Thus, rectangular resists 6a are formed at positions respectively corresponding to the photodiodes of the pixel portions by being spaced from one another by predetermined intervals.

Subsequently, as shown in FIGS. 3B and 4B, a thermal reflow process is performed on the resists 6a at a predetermined temperature. Thus, cross-sectionally upwardly-convex-lens-like-shaped resists 6b are formed by rounding off corner portions.

Next, as shown in FIGS. 3C and 4C, the lens-like resists 6b are cured by being ion-implanted. Thus, convex lenses 6c are formed. Each of steps illustrated in FIGS. 3A to 3C and FIGS. 4A to 4C correspond to the above lens forming step according to the invention.

Incidentally, a method performed in the lens forming step is not limited to the above method. For example, the following method can be employed. First, first resists for excimer laser exposure or ultraviolet exposure are applied onto the planarized film 5. Then, second resists are applied onto the first resists. Subsequently, each of the second resists is patterned. Thus, rectangular resists are formed on the first resists. After the rectangularly formed resists are thermally fused to obtain lens-shaped resists, the lens-shaped resists are transferred onto the first resists. Subsequently, the lenses 6c are formed by performing ion-implanting on the resists obtained by the transfer.

According to the present embodiment, a plurality of lenses 6c are formed so that in a case where one of the plurality of finally formed lenses 6c is selected as the lens 6c of interest, the distance between the lens 6c of interest and the lens 6c adjoining the lens 6c of interest changes according to a color detected by the photodiode provided under the lens 6c of interest. Thus, the focal length of each of the R-microlens 8, the G-microlens 8, and the B-microlens 8 can be changed.

The distance between the lenses 6c depends on that between the rectangular resists 6a. Thus, the focal length of each of the R-microlens 8, the G-microlens 8, and the B-microlens 8 can be changed by preliminarily adjusting the size and the placement of each of the rectangular resists 6a when forming the resists 6a.

Thus, before patterning the resists, in a state in which all the pixel portions are assumed to be R-pixel portions, the present embodiment determines the size and the placement of each of the resists 6a so that the gap from each of the resists 6 to the adjacent resist 6a has a value corresponding to the wavelength of R-light. The determined size and the determined placement are applied to the resist 6a to be formed in each of the R-pixel portions. Subsequently, in a state in which all the pixel portions are assumed to be G-pixel portions, the present embodiment determines the size and the placement of each of the resists 6a so that the gap from each of the resists 6 to the adjacent resist 6a has a value corresponding to the wavelength of G-light. The size and the placement determined this time are applied to the resist 6a to be formed in each of the G-pixel portions. Next, in a state in which all the pixel portions are assumed to be B-pixel portions, the present embodiment determines the size and the placement of each of the resists 6a so that the gap from each of the resists 6 to the adjacent resist 6a has a value corresponding to the wavelength of B-light. The size and the placement determined this time are applied to the resist 6a to be formed in each of the B-pixel portions.

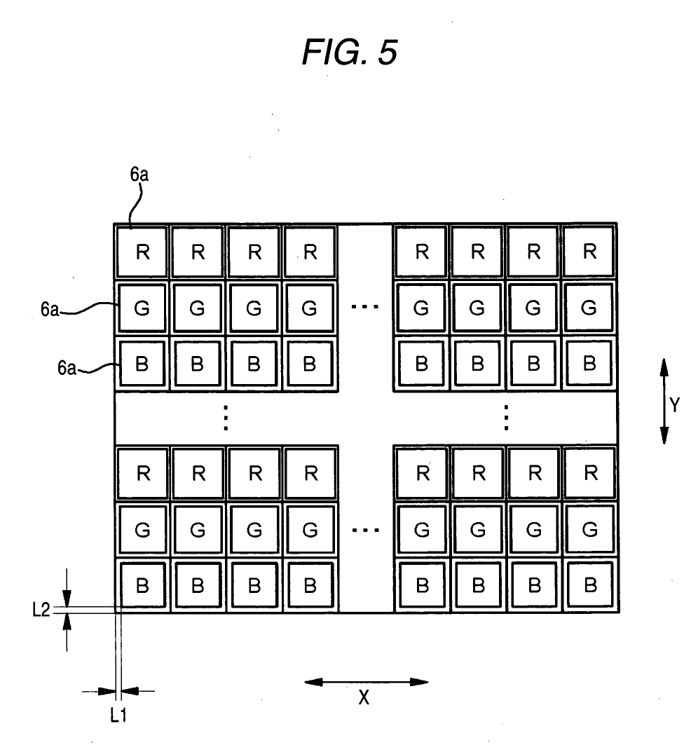

Then, patterning is performed on the resists according to the size and the placement of each of the resists. FIG. 5 is a plan view of the solid-state imaging device obtained after performing resist-patterning. As shown in FIG. 5, the distance L1 from an end part in an X-direction of the resist 6a formed in each of the pixel portions to an end part in the X-direction of the pixel portion, in which the resist 6a is formed, is equal to the distance L2 from an end part in a Y-direction of the resist 6a formed in each of the pixel portions to an end part in the Y-direction of the pixel portion in which the resist 6a is formed. Among the distances L1 and L2 of the pixel portions, those of the B-pixel portions are largest, while those of the R-pixel portion are smallest.

Thus, among the distances from each of the resists 6a to the other adjacent resists 6a, the minimum insurable distance L1 changes according to a color detected by the corresponding pixel portion. Therefore, in a case where one of a plurality of lenses 6c is selected as the lens 6c of interest, the distance from the lens 6c of interest to another of the lenses 6c, which adjoins the lens 6c of interest, changes according to a color detected by the photodiode provided under the lens 6c of interest.

Then, after the lens 6c is formed, the overcoat film 7a (that is, a film adapted to adjust the curvature of the lens 6c), which is made of a material that is the same as the material of the resist 6a and has a viscosity lower than the viscosity of the resist 6a, is formed on the lens 6c by a spin-coating method. Subsequently, as shown in FIGS. 3E and 4E, the overcoat film 7a is cured by performing ion-implantation. Consequently, desired microlenses 8, each of which includes the lens 6c and a part of the overcoat film 7b, are obtained.

When spin-coating is performed, the overcoat material flows into the gap between the lenses 6c, which are respectively formed in the R-pixel portions and adjoin each other, as shown in FIGS. 3A to 3E. The overcoat material having flowed thereinto cannot spread very much in parallel to the planarized film 5. Thus, the overcoat film's thickness in a direction perpendicular to the planarized film 5 becomes large. Consequently, the curvature of the R-microlens 8 is adjusted to a value less than the curvature of the lens 6c.

Also, the overcoat material flows into the gap between the lenses 6c, which are respectively formed in the B-pixel portions and adjoin each other, as shown in FIGS. 4A to 4E. The overcoat material having flowed thereinto spreads thinly in parallel to the planarized film 5. Thus, the overcoat film's thickness in a direction perpendicular to the planarized film 5 is not very large. Consequently, the curvature of the R-microlens 8 is maintained at a value close to that of the curvature of the lens 6c.

Additionally, although not shown, similarly, the curvature of the G-microlens 8 is adjusted. The curvature of the G-microlens 8 is larger than that of the R-microlens 8 and is smaller than that of the B-microlens 8.

In each of the pixel portions, the size of the gap between the lenses 6c adjoining each other in the X-direction differs from that of the gap between the lenses 6c adjoining each other in the Y-direction. However, whatever the size of the lens 6c formed adjoining the lens 6c of interest is, the gap between the lens 6c of interest and the adjacent lens 6c tends to become small in a case where the above distance L1 (=the distance L2) is small. Conversely, in a case where the above distance L1 (=the distance L2) is large, the gap between the lens 6c of interest and the adjacent lens 6c tends to become large. Thus, nearly similarly, the curvature of the microlens can be adjusted in the Y-direction.

Incidentally, as shown in FIGS. 3C and 4C, the size of the resist 6a varies with the position thereof. Thus, the curvature of the lens 6c also varies with the position thereof. Therefore, in a case where the gapless microlenses 8 are not necessarily required, the lenses 8 can be utilized, without being changed, as the microlenses 8. However, the difference in curvature among the lenses 6c is minute. It is difficult to provide a large difference in the curvature thereamong. Thus, it is difficult to expand a range, in which the curvature of the microlens 8 is controlled, without change in the microlens 8. In accordance with the method according to the present embodiment, the adjustment of the gap between the lenses 6c is combined with the formation of the overcoat film, so that the range, in which the curvature of the microlens 8 is controlled, can easily be expanded.

Also, as can be understood from comparison between FIGS. 3A to 3E and FIGS. 4A to 4E, the light collecting area of the R-microlens 8 is larger than that of the B-microlens 8. The light collecting effect of the R-microlens 8 is higher than that of the B-microlens 8. Especially, the R-microlens 8 can efficiently collect oblique light. Thus, when manufacturing a solid-state imaging device having a high-sensitivity photodiode and a low-sensitivity photodiode, the aforementioned method can be employed. The solid-state imaging device having a high-sensitivity photodiode and a low-sensitivity photodiode is assumed to be configured so that the photodiodes have same apertures, and that a difference in sensitivity is provided to the photodiodes by causing the light collecting efficiencies of the microlenses respectively provided above the apertures of the photodiodes to differ from each other.

For example, it is advisable to form the lenses 6c so that the distance between the lens 6c, which is provided above the photodiode configured to have high sensitivity, and the adjacent lens 6c is relatively small, and that the distance between the lens 6c, which is provided above the photodiode configured to have low sensitivity, and the adjacent lens 6c is relatively large. Thus, it is advisable to form a plurality of lenses 6c so that in a case where one of the plurality of finally formed lenses 6c is selected as the lens 6c of interest, the distance between the lens 6c of interest and another of the lenses 6c, which adjoins the lens 6c of interest, changes according to the sensitivity of the photodiode provided under the lens 6c of interest.

Also, the aforementioned manufacturing method can be utilized to reduce luminance shading caused in a solid-state imaging device. For example, it is advisable to form the lenses 6c so that the distance from the lens 6c formed above each of the photodiodes disposed in a peripheral portion of the solid-state imaging device, in which the luminance shading prominently occurs, to the adjacent lens 6c is relatively small, and that the distance from the lens 6c formed above each of the photodiodes disposed in a central portion of the solid-state imaging device, in which the luminance shading is insignificant, to the adjacent lens 6c is relatively large. Thus, it is advisable to form a plurality of lenses 6c so that in a case where one of the plurality of finally formed lenses 6c is selected as the lens 6c of interest, the distance between the lens 6c of interest and another of the lenses 6c, which adjoins the lens 6c of interest, changes according to the position of the photodiode provided under the lens 6c of interest.

Incidentally, examples of the feature of the photoelectric conversion element are what color the transducer detects, what sensitivity the transducer detects, and what position the transducer is placed at. That is, the color detected by the photoelectric conversion element, the sensitivity of the photoelectric conversion element, and the position of the photoelectric conversion element are the features of the photoelectric conversion element.

Additionally, preferably, the gap between the above lenses 6c ranges from 0.1 μm to 0.5 μm.

While the invention has been described with reference to the exemplary embodiments, the technical scope of the invention is not restricted to the description of the exemplary embodiments. It is apparent to the skilled in the art that various changes or improvements can be made. It is apparent from the description of claims that the changed or improved configurations can also be included in the technical scope of the invention.

This application claims foreign priority from Japanese Patent Application No. 2005-346449, filed Nov. 30, 2005, the entire disclosure of which is herein incorporated by reference.

What is claimed is:

1. A solid-state imaging device comprising:
a plurality of photoelectric conversion elements; and
a plurality of microlenses above the plurality of photoelectric conversion elements, the microlenses having no gap between adjacent two microlenses
wherein each of the plurality of microlenses has a focal length according to a color detected by a photoelectric conversion element under the each the plurality of the microlenses.

2. The solid-state imaging device according to claim 1, wherein each of the plurality of microlenses includes a convex lens and an overcoat film, the overcoat film being over the convex lens and adjusting a curvature of the convex lens.

3. A method for manufacturing a solid-state imaging device comprising microlenses having no gap between adjacent two microlenses, which comprise manufacturing the microlenses,
wherein the manufacturing of the microlenses comprises:
forming a plurality of convex lenses above a plurality of photoelectric conversion elements; and
forming an overcoat film on the plurality of convex lenses, the overcoat film adjusting a curvature of each of the plurality of convex lenses, and
wherein in the forming of the plurality of convex lenses, the plurality of convex lenses are formed so that when one of the plurality of convex lenses is selected as a lens, a distance between the lens and a convex lens adjacent to the lens changes according to a feature of a photoelectric conversion element under the lens.

4. The method according to claim 3, wherein the feature of the photoelectric conversion element is a color detected by the photoelectric conversion element.

5. The method according to claim 3, wherein the feature of the photoelectric conversion element is a sensitivity of the photoelectric conversion element.

6. The method according to claim 3, wherein the feature of the photoelectric conversion element is a position of the photoelectric conversion element.
